(19) United States
(12) Patent Application Publication
(10) Pub. No.: US 2023/0197750 A1
(43) Pub. Date: Jun. 22, 2023

(54) SINGLE-PHOTON AVALANCHE DIODE COVERED BY MULTIPLE MICROLENSES

(71) Applicant: SEMICONDUCTOR COMPONENTS INDUSTRIES, LLC, Phoenix, AZ (US)

(72) Inventors: Marc Allen SULFRIDGE, Boise, ID (US); Andrew Eugene PERKINS, Boise, ID (US)

(73) Assignee: SEMICONDUCTOR COMPONENTS INDUSTRIES, LLC, Phoenix, AZ (US)

(21) Appl. No.: 17/644,909

(22) Filed: Dec. 17, 2021

(51) Int. Cl. H01L 27/146; G02B 3/06; G02B 3/00; H01L 31/0216

(52) U.S. Cl. CPC H01L 27/14627; G02B 3/06; G02B 3/0043; H01L 31/02161; G02B 2003/0093; H01L 31/107

(57) ABSTRACT

An imaging device may include single-photon avalanche diodes (SPADs). Each SPAD may be overlapped by multiple microlenses. The microlenses over each SPAD may include first microlenses having a first size over a central portion of the SPAD and second microlenses having a second size that is greater than the first size over a peripheral area of the SPAD. The second microlenses may be spherical microlenses or cylindrical microlenses. The first microlenses may be aligned with underlying light scattering structures to improve the efficiency of the light scattering structures. The second microlenses may partially overlap isolation structures to direct light away from the isolation structures and towards the SPAD.

### BACKGROUND

This relates generally to imaging systems and, more particularly, to imaging systems that include single-photon avalanche diodes (SPADs) for single photon detection.

Modern electronic devices such as cellular telephones, cameras, and computers often use digital image sensors. Image sensors (sometimes referred to as imagers) may be formed from a two-dimensional array of image sensing pixels. Each pixel typically includes a photosensitive element (such as a photodiode) that receives incident photons (light) and converts the photons into electrical signals.

Conventional image sensors may suffer from limited functionality in a variety of ways. For example, some conventional image sensors may not be able to determine the distance from the image sensor to the objects that are being imaged. Conventional image sensors may also have lower than desired image quality and resolution.

To improve sensitivity to incident light, single-photon avalanche diodes (SPADs) may sometimes be used in imaging systems. Single-photon avalanche diodes may be capable of single-photon detection.

It is within this context that the embodiments described herein arise.

### BRIEF DESCRIPTION OF THE DRAWINGS

FIG. 1 is a circuit diagram showing an illustrative single-photon avalanche diode pixel in accordance with an embodiment.

FIG. 2 is a diagram of an illustrative silicon photomultiplier in accordance with an embodiment.

FIG. 3 is a diagram of an illustrative silicon photomultiplier with a fast output terminal in accordance with an embodiment.

FIG. 4 is a diagram of an illustrative silicon photomultiplier comprising an array of microcells.

FIG. 5 is a diagram of an illustrative imaging system that includes a SPAD-based semiconductor device in accordance with an embodiment.

FIG. 6 is a diagram of an illustrative vehicle having an imaging system in accordance with an embodiment.

FIG. 7 is a cross-sectional side view of an illustrative SPAD-based semiconductor device with multiple microlenses over each SPAD in accordance with an embodiment.

FIG. 8 is a top view of an illustrative microcell with microlenses of different sizes including larger microlenses around a periphery of the SPAD in accordance with an embodiment.

FIG. 9 is a top view of an illustrative microcell with an array of microlenses of uniform size in accordance with an embodiment.

FIG. 10 is a top view of an illustrative microcell with cylindrical microlenses in accordance with an embodiment.

FIG. 11A is a cross-sectional side view of illustrative microlenses separated by gaps in accordance with an embodiment.

FIG. 11B is a cross-sectional side view of illustrative gapless microlenses in accordance with an embodiment.

FIG. 12 is a flowchart of illustrative method steps that may be used to form microlenses over a microcell in accordance with an embodiment.

### DETAILED DESCRIPTION

Embodiments of the present technology relate to imaging systems that include single-photon avalanche diodes (SPADs).

Some imaging systems include image sensors that sense light by converting impinging photons into electrons or holes that are integrated (collected) in pixel photodiodes within the sensor array. After completion of an integration cycle, collected charge is converted into a voltage, which is supplied to the output terminals of the sensor. In complementary metal-oxide semiconductor (CMOS) image sensors, the charge to voltage conversion is accomplished directly in the pixels themselves, and the analog pixel voltage is transferred to the output terminals through various pixel addressing and scanning schemes. The analog pixel voltage can also be later converted on-chip to a digital equivalent and processed in various ways in the digital domain.

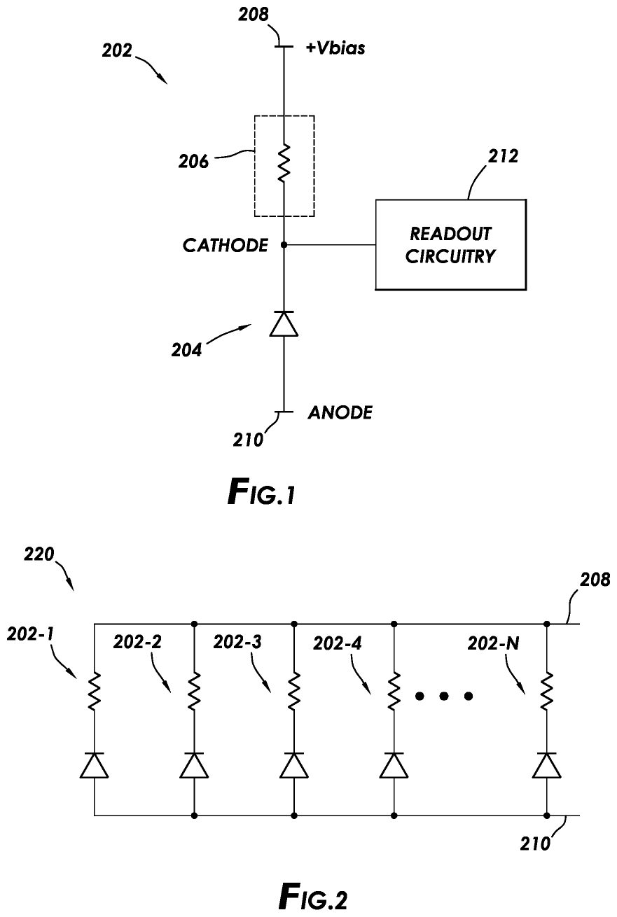

In single-photon avalanche diode (SPAD) devices (such as the ones described in connection with FIGS. 1-4), on the other hand, the photon detection principle is different. The light sensing diode is biased above its breakdown point, and when an incident photon generates an electron or hole, this carrier initiates an avalanche breakdown with additional carriers being generated. The avalanche multiplication may produce a current signal that can be easily detected by readout circuitry associated with the SPAD. The avalanche process can be stopped (or quenched) by lowering the diode bias below its breakdown point. Each SPAD may therefore include a passive and/or active quenching circuit for halting the avalanche.

This concept can be used in two ways. First, the arriving photons may simply be counted (e.g., in low light level applications). Second, the SPAD pixels may be used to measure photon time-of-flight (ToF) from a synchronized light source to a scene object point and back to the sensor, which can be used to obtain a 3-dimensional image of the scene.

FIG. 1 is a circuit diagram of an illustrative SPAD device 202. As shown in FIG. 1, SPAD device 202 includes a SPAD 204 that is coupled in series with quenching circuitry 206 between a first supply voltage terminal 210 (e.g., a ground power supply voltage terminal) and a second supply voltage terminal 208 (e.g., a positive power supply voltage terminal). In particular, SPAD device 202 includes a SPAD 204 having an anode terminal connected to power supply voltage terminal 210 and a cathode terminal connected directly to quenching circuitry 206. SPAD device 202 that includes SPAD 204 connected in series with a quenching resistor 206 is sometimes referred to collectively as a photo-triggered unit or “microcell.” During operation of SPAD device 202, supply voltage terminals 208 and 210 may be used to bias SPAD 204 to a voltage that is higher than the breakdown voltage (e.g., bias voltage Vbias is applied to terminal 208). Breakdown voltage is the largest reverse voltage that can be applied to SPAD 204 without causing an exponential increase in the leakage current in the diode. When SPAD 204 is reverse biased above the breakdown voltage in this manner, absorption of a single-photon can trigger a short-duration but relatively large avalanche current through impact ionization.

Quenching circuitry 206 (sometimes referred to as quenching element 206) may be used to lower the bias voltage of SPAD 204 below the level of the breakdown voltage. Lowering the bias voltage of SPAD 204 below the breakdown voltage stops the avalanche process and corresponding avalanche current. There are numerous ways to form quenching circuitry 206. Quenching circuitry 206 may be passive quenching circuitry or active quenching circuitry. Passive quenching circuitry may, without external control or monitoring, automatically quench the avalanche current once initiated. For example, FIG. 1 shows an example where a resistor component is used to form quenching circuitry 206. This is an example of passive quenching circuitry.

This example of passive quenching circuitry is merely illustrative. Active quenching circuitry may also be used in SPAD device 202. Active quenching circuitry may reduce the time it takes for SPAD device 202 to be reset. This may allow SPAD device 202 to detect incident light at a faster rate than when passive quenching circuitry is used, improving the dynamic range of the SPAD device. Active quenching circuitry may modulate the SPAD quench resistance. For example, before a photon is detected, quench resistance is set high and then once a photon is detected and the avalanche is quenched, quench resistance is minimized to reduce recovery time.

SPAD device 202 may also include readout circuitry 212. There are numerous ways to form readout circuitry 212 to obtain information from SPAD device 202. Readout circuitry 212 may include a pulse counting circuit that counts arriving photons. Alternatively or in addition, readout circuitry 212 may include time-of-flight circuitry that is used to measure photon time-of-flight (ToF). The photon time-of-flight information may be used to perform depth sensing. In one example, photons may be counted by an analog counter to form the light intensity signal as a corresponding pixel voltage. The ToF signal may be obtained by also converting the time of photon flight to a voltage. The example of an analog pulse counting circuit being included in readout circuitry 212 is merely illustrative. If desired, readout circuitry 212 may include digital pulse counting circuits. Readout circuitry 212 may also include amplification circuitry if desired.

The example in FIG. 1 of readout circuitry 212 being coupled to a node between diode 204 and quenching circuitry 206 is merely illustrative. Readout circuitry 212 may be coupled to terminal 208 or any desired portion of the SPAD device. In some cases, quenching circuitry 206 may be considered integral with readout circuitry 212.

Because SPAD devices can detect a single incident photon, the SPAD devices are effective at imaging scenes with low light levels. Each SPAD may detect the number of photons that are received within a given period of time (e.g., using readout circuitry that includes a counting circuit). However, as discussed above, each time a photon is received and an avalanche current initiated, the SPAD device must be quenched and reset before being ready to detect another photon. As incident light levels increase, the reset time becomes limiting to the dynamic range of the SPAD device (e.g., once incident light levels exceed a given level, the SPAD device is triggered immediately upon being reset).

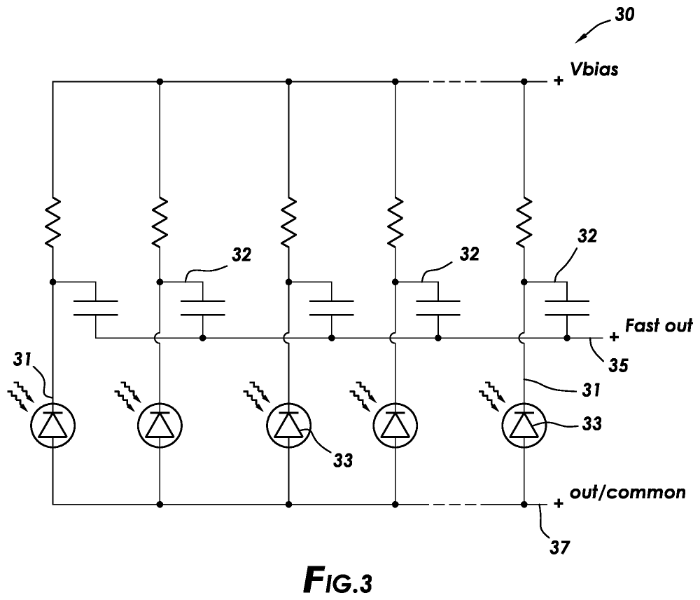

Multiple SPAD devices may be grouped together to help increase dynamic range. FIG. 2 is a circuit diagram of an illustrative group 220 of SPAD devices 202. The group or array of SPAD devices may sometimes be referred to as a silicon photomultiplier (SiPM). As shown in FIG. 2, silicon photomultiplier 220 may include multiple SPAD devices that are coupled in parallel between first supply voltage terminal 208 and second supply voltage terminal 210. FIG. 2 shows N SPAD devices 202 coupled in parallel (e.g., SPAD device 202-1, SPAD device 202-2, SPAD device 202-3, SPAD device 202-4, . . . , SPAD device 202-N). More than two SPAD devices, more than ten SPAD devices, more than one hundred SPAD devices, more than one thousand SPAD devices, etc. may be included in a given silicon photomultiplier 220.

Each SPAD device 202 may sometimes be referred to herein as a SPAD pixel 202. Although not shown explicitly in FIG. 2, readout circuitry for the silicon photomultiplier 220 may measure the combined output current from all of SPAD pixels in the silicon photomultiplier. Configured in this way, the dynamic range of an imaging system including the SPAD pixels may be increased. Each SPAD pixel is not guaranteed to have an avalanche current triggered when an incident photon is received. The SPAD pixels may have an associated probability of an avalanche current being triggered when an incident photon is received. There is a first probability of an electron being created when a photon reaches the diode and then a second probability of the electron triggering an avalanche current. The total probability of a photon triggering an avalanche current may be referred to as the SPAD's photon-detection efficiency (PDE). Grouping multiple SPAD pixels together in the silicon photomultiplier therefore allows for a more accurate measurement of the incoming incident light. For example, if a single SPAD pixel has a PDE of 50% and receives one photon during a time period, there is a 50% chance the photon will not be detected. With the silicon photomultiplier 220 of FIG. 2, chances are that two of the four SPAD pixels will detect the photon, thus improving the provided image data for the time period.

The example of FIG. 2 in which the plurality of SPAD pixels 202 share a common output in silicon photomultiplier 220 is merely illustrative. In the case of an imaging system including a silicon photomultiplier having a common output for all of the SPAD pixels, the imaging system may not have any resolution in imaging a scene (e.g., the silicon photomultiplier can just detect photon flux at a single point). It may be desirable to use SPAD pixels to obtain image data across an array to allow a higher resolution reproduction of the imaged scene. In cases such as these, SPAD pixels in a single imaging system may have per-pixel readout capabilities. Alternatively, an array of silicon photomultipliers (each including more than one SPAD pixel) may be included in the imaging system. The outputs from each pixel or from each silicon photomultiplier may be used to generate image data for an imaged scene. The array may be capable of independent detection (whether using a single SPAD pixel or a plurality of SPAD pixels in a silicon photomultiplier) in a line array (e.g., an array having a single row and multiple columns or a single column and multiple rows) or an array having more than ten, more than one hundred, or more than one thousand rows and/or columns.

While there are a number of possible use cases for SPAD pixels as discussed above, the underlying technology used to detect incident light is the same. All of the aforementioned examples of devices that use SPAD pixels may collectively be referred to as SPAD-based semiconductor devices. A silicon photomultiplier with a plurality of SPAD pixels having a common output may be referred to as a SPAD-based semiconductor device. An array of SPAD pixels with per-pixel readout capabilities may be referred to as a SPAD-based semiconductor device. An array of silicon photomultipliers with per-silicon-photomultiplier readout capabilities may be referred to as a SPAD-based semiconductor device.

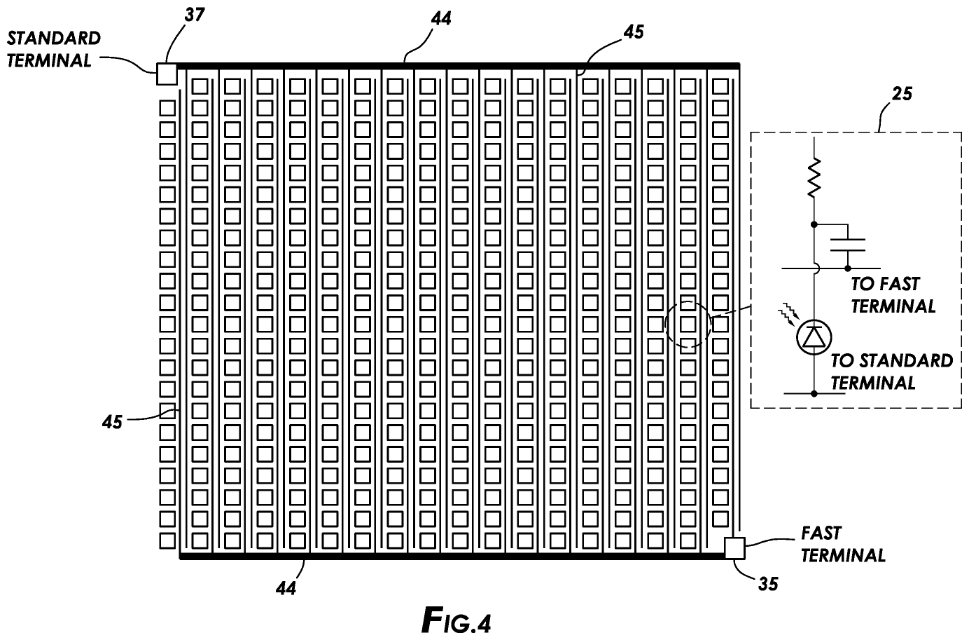

FIG. 3 illustrates a silicon photomultiplier 30. As shown in FIG. 3, SiPM 30 has a third terminal 35 which is capacitively coupled to each cathode terminal 31 in order to provide a fast readout of the avalanche signals from the SPADs 33. When then SPADs 33 emits a current pulse, part of the resulting change in voltage at the cathode 31 will be coupled via the mutual capacitance into the third (“fast”) output terminal 35. Using the third terminal 35 for readout avoids the compromised transient performance resulting from the relatively large RC time constant associated with the biasing circuit that biases the top terminal of the quenching resistor.

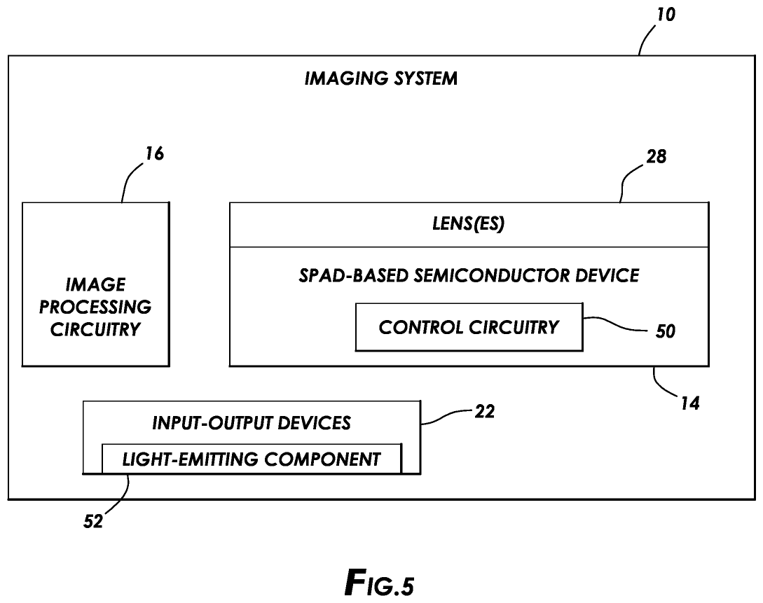

It will be appreciated by those skilled in the art that silicon photomultipliers include major bus lines 44 and minor bus lines 45 as illustrated in FIG. 4. The minor bus lines 45 may connect directly to each individual microcell 25. The minor bus lines 45 are then coupled to the major bus lines 44 which connect to the bond pads associated with terminals 37 and 35. Typically, the minor bus lines 45 extend vertically between the columns of microcells 25, whereas the major bus lines 44 extend horizontally adjacent the outer row of the microcells 25.

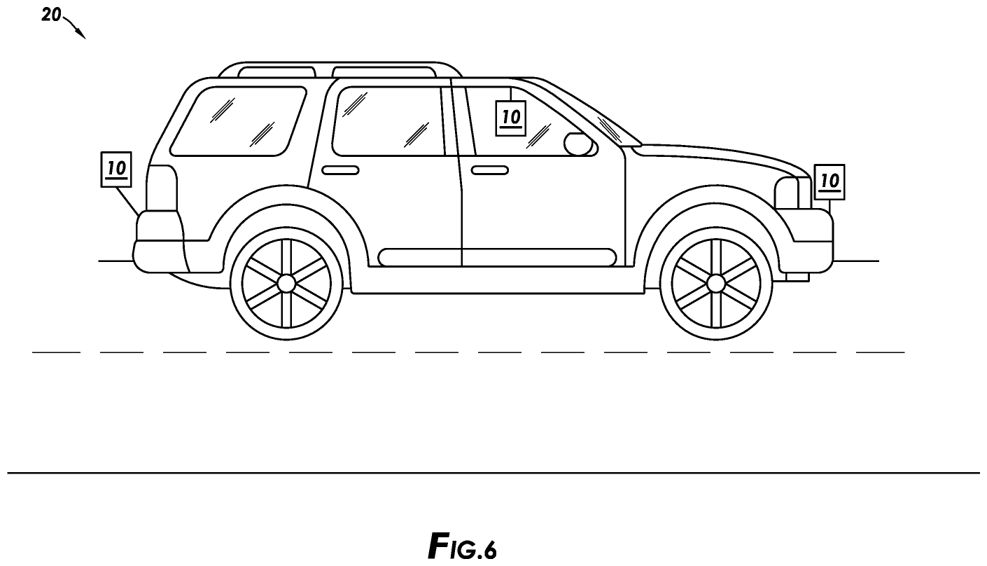

An imaging system 10 with a SPAD-based semiconductor device is shown in FIG. 5. Imaging system 10 may be an electronic device such as a digital camera, a computer, a cellular telephone, a medical device, or other electronic device. Imaging system 10 may be an imaging system on a vehicle (sometimes referred to as vehicular imaging system). Imaging system 10 may be used for LIDAR applications. Imaging system 10 may sometimes be referred to as a SPAD-based imaging system.

Imaging system 10 may include one or more SPAD-based semiconductor devices 14 (sometimes referred to as semiconductor devices 14, devices 14, SPAD-based image sensors 14, or image sensors 14). One or more lenses 28 may optionally cover each semiconductor device 14. During operation, lenses 28 (sometimes referred to as optics 28) may focus light onto SPAD-based semiconductor device 14. SPAD-based semiconductor device 14 may include SPAD pixels that convert the light into digital data. The SPAD-based semiconductor device may have any number of SPAD pixels (e.g., hundreds, thousands, millions, or more). In some SPAD-based semiconductor devices, each SPAD pixel may be covered by a respective color filter element and/or microlens.

SPAD-based semiconductor device 14 may include circuitry such as control circuitry 50. The control circuitry for the SPAD-based semiconductor device may be formed either on-chip (e.g., on the same semiconductor substrate as the SPAD devices) or off-chip (e.g., on a different semiconductor substrate as the SPAD devices). The control circuitry may control operation of the SPAD-based semiconductor device. For example, the control circuitry may operate active quenching circuitry within the SPAD-based semiconductor device, may control a bias voltage provided to bias voltage supply terminal 208 of each SPAD, may control/monitor the readout circuitry coupled to the SPAD devices, etc.

The SPAD-based semiconductor device 14 may optionally include additional circuitry such as logic gates, digital counters, time-to-digital converters, bias circuitry (e.g., source follower load circuits), sample and hold circuitry, correlated double sampling (CDS) circuitry, amplifier circuitry, analog-to-digital (ADC) converter circuitry, data output circuitry, memory (e.g., buffer circuitry), address circuitry, etc. Any of the aforementioned circuits may be considered part of the control circuitry 50 of FIG. 5.

Image data from SPAD-based semiconductor device 14 may be provided to image processing circuitry 16. Image processing circuitry 16 may be used to perform image processing functions such as automatic focusing functions, depth sensing, data formatting, adjusting white balance and exposure, implementing video image stabilization, face detection, etc. For example, during automatic focusing operations, image processing circuitry 16 may process data gathered by the SPAD pixels to determine the magnitude and direction of lens movement (e.g., movement of lens 28) needed to bring an object of interest into focus. Image processing circuitry 16 may process data gathered by the SPAD pixels to determine a depth map of the scene. In some cases, some or all of control circuitry 50 may be formed integrally with image processing circuitry 16.

Imaging system 10 may provide a user with numerous high-level functions. In a computer or advanced cellular telephone, for example, a user may be provided with the ability to run user applications. To implement these functions, the imaging system may include input-output devices 22 such as keypads, buttons, input-output ports, joysticks, and displays. Additional storage and processing circuitry such as volatile and nonvolatile memory (e.g., random-access memory, flash memory, hard drives, solid state drives, etc.), microprocessors, microcontrollers, digital signal processors, application specific integrated circuits, and/or other processing circuits may also be included in the imaging system.

Input-output devices 22 may include output devices that work in combination with the SPAD-based semiconductor device. For example, a light-emitting component 52 may be included in the imaging system to emit light (e.g., infrared light or light of any other desired type). Light-emitting component 52 may be a laser, light-emitting diode, or any other desired type of light-emitting component. Semiconductor device 14 may measure the reflection of the light off of an object to measure distance to the object in a LIDAR (light detection and ranging) scheme. Control circuitry 50 that is used to control operation of the SPAD-based semiconductor device may also optionally be used to control operation of light-emitting component 52. Image processing circuitry 16 may use known times (or a known pattern) of light pulses from the light-emitting component while processing data from the SPAD-based semiconductor device.

In a vehicular imaging system, data from SPAD-based semiconductor device 14 may be used to determine environmental conditions surrounding the vehicle. The vehicular imaging system may include an external SPAD-based semiconductor device 14 that captures images of the vehicle's surroundings or an in-cabin SPAD-based semiconductor device 14 that captures images of the interior of the vehicle (e.g., of the driver). As examples, vehicular imaging system may include systems such as a parking assistance system, an automatic or semi-automatic cruise control system, an auto-braking system, a collision avoidance system, a lane keeping system (sometimes referred to as a lane drift avoidance system), a pedestrian detection system, etc. In at least some instances, the vehicular imaging system may form part of a semi-autonomous or autonomous self-driving vehicle. System 10 may also be used for medical imaging, surveillance, and general machine vision applications.

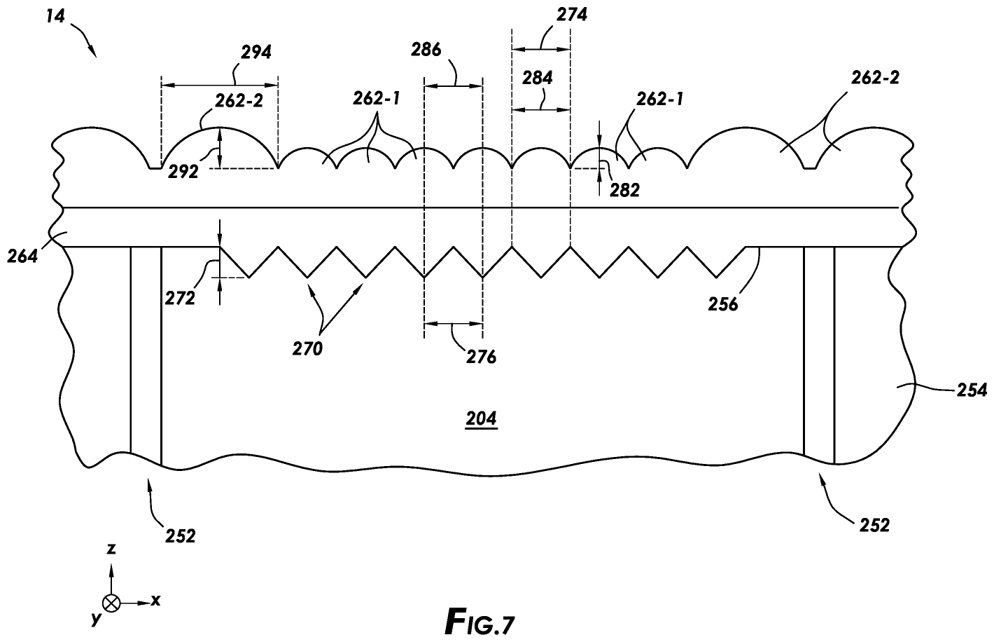

An illustrative example of a vehicle 20 such as an automobile is shown in FIG. 6. As shown in the illustrative example of FIG. 6, automobile 20 may include one or more imaging systems 10. The imaging systems may be vehicular safety systems as discussed above. In the illustrative example of FIG. 6, a first imaging system 10 is shown mounted on the front of car 20 (e.g., to capture images of the surroundings in front of the car), and a second imaging system 10 is shown mounted in the interior of car 20 (e.g., to capture images of the driver of the vehicle). If desired, an imaging system 10 may be mounted at the rear end of vehicle 20 (i.e., the end of the vehicle opposite the location at which first imaging system 10 is mounted in FIG. 6). The imaging system at the rear end of the vehicle may capture images of the surroundings behind the vehicle. These examples are merely illustrative. One or more imaging systems 10 may be mounted on or within a vehicle 20 at any desired location(s).

The likelihood of a photon being absorbed (e.g., the absorption percentage) increases with increasing semiconductor depth. To improve the sensitivity of a SPAD-based semiconductor device, it would therefore be desirable to increase the thickness of the semiconductor substrate. However, manufacturing considerations and other design factors may prevent or discourage semiconductor substrates from being thick enough for a target absorption percentage. To increase the absorption percentage without increasing semiconductor substrate thickness, light scattering structures may be included in the SPAD-based semiconductor device. The scattering structures may scatter incident light (e.g., using a low-index material that fills trenches in the semiconductor substrate), thereby increasing the path length of the light through the semiconductor substrate and increasing the probability of the incident light being absorbed by the semiconductor. Scattering the incident light (using refraction and/or diffraction) to increase the path length may be particularly helpful for incident light of higher wavelengths. Scattering incident light may improve absorption efficiency but may also make the SPAD-based semiconductor device susceptible to crosstalk. Isolation structures may be included around each SPAD to prevent cross-talk between adjacent microcells. The SPAD-based semiconductor devices described herein may be used to sense near infrared light or light of any other desired type.

In some cases, the SPADs in SPAD-based semiconductor device 14 may have lengths and widths that are greater than 10 microns. A single microlens may cover a SPAD of this type. However, the microlens may have a minimum thickness requirement (e.g., multiple microns) to focus light onto the large underlying SPAD. To avoid manufacturing difficulties associated with thick microlenses of this type, each SPAD may instead by overlapped by multiple, smaller microlenses. The small microlenses may be easier to manufacture and may be aligned with scattering structures to improve the effectiveness of the scattering structures.

FIG. 7 is a cross-sectional side view of an illustrative SPAD-based semiconductor device having scattering structures and microlenses of different sizes. SPAD-based semiconductor device 14 includes a SPAD 204. Each SPAD may be considered part of a respective SPAD device, SPAD pixel, or microcell (e.g., microcell 202 in FIG. 1). The SPAD-based semiconductor device 14 in FIG. 7 is a backside illuminated (BSI) device (e.g., incident light passes through the back surface of the substrate). SPAD 204 may be isolated from the adjacent SPADs by isolation structures such as isolation structures 252.

As shown in FIG. 7, SPAD 204 is formed in a substrate 254 (e.g., a semiconductor substrate formed from a material such as silicon) that extends between the back surface 256 and a front surface. Substrate 254 may be formed by a p-type doped semiconductor layer (e.g., p-type doped epitaxial silicon).

Isolation structures 252 may include a trench with one or more filler materials. The trench may be etched from the front side of the substrate (e.g., from the front surface towards back surface 256) or may be etched from the back side of the substrate (e.g., from the back surface 256 towards the front surface). The isolation structures 252 may include a light absorbing filler or a low-index material in the trench. The light absorbing filler may be formed from a metal such as tungsten and may therefore sometimes be referred to as metal filler or tungsten filler. The metal filler absorbs incident photons and improves isolation between SPAD 204 and adjacent SPADs. A buffer layer may be formed adjacent to metal filler (e.g., between the metal filler and the substrate) in isolation structures 252. The buffer layer may be any desired material (e.g., silicon dioxide) and may be compatible with both the material of metal filler and the materials surrounding isolation structures 252 (e.g., silicon). A high dielectric constant layer may also be included in the trench if desired. Isolation structures 252 may be deep-trench isolation structures. The isolation structures 252 may form a partial or complete ring around SPAD 204. Isolation structures 252 may optionally include a p-type doped liner. The p-type doped liner may be formed by doped portions of the semiconductor substrate adjacent to the trench for isolation structures 252. The p-type doped liner may suppress dark current.

Scattering structures 270 may also be formed in substrate 254. Scattering structures 270 may be configured to scatter incident light (e.g., using a low-index material that fills trenches in substrate 254), thereby increasing the path length of the light through the semiconductor substrate and increasing the probability of the incident light being absorbed by the semiconductor. Scattering the incident light (using refraction and/or diffraction) to increase the path length may be particularly helpful for incident light of higher wavelengths (e.g., near infrared light).

The material(s) that fill the trenches (e.g., buffer 264 shown in FIG. 7, an optional passivation layer in direct contact with substrate 254, etc.) of light scattering structures 270 may have a lower refractive index than substrate 254 (e.g., a refractive index that is lower by more than 0.1, more than 0.2, more than 0.3, more than 0.5, more than 1.0, more than 1.5, more than 2.0, etc.). The low-index material in the trenches causes refractive scattering of incident light.

Scattering structures 270 scatter incident light, thereby increasing the path length of the light through the semiconductor substrate and increasing the probability of the incident light being absorbed by the semiconductor. Isolation structures 252 help prevent the scattered light from reaching an adjacent SPAD and causing cross-talk. In addition to preventing crosstalk of these primary emissions (e.g., photons from incident light), the isolation structures 252 may prevent crosstalk caused by secondary emissions (e.g., photons produced when an avalanche occurs in the SPAD).

The scattering structures may be formed using backside trenches (e.g., trenches that extend from back surface 256 towards the front surface). The backside trenches may be filled by various materials such as a high dielectric constant coating and a buffer layer such as buffer layer 264. The high dielectric constant coating (sometimes referred to as high k coating or passivation layer) may mitigate dark current. As one example, the passivation coating may be an oxide coating (e.g., aluminum oxide, hafnium oxide, tantalum oxide, etc.). A dielectric layer 264 (sometimes referred to as a buffer layer) may be formed over the passivation coating. The dielectric layer 264 may be formed from silicon dioxide or another desired material.

The light scattering structures each have a height 272 (sometimes referred to as depth) and a width 274. The light scattering structures also have a pitch 276 (e.g., the center-to-center separation between each light scattering structure). In general, each scattering structure may have a height 272 of less than 5 micron, less than 3 micron, less than 2 micron, less than 1 micron, less than 0.5 micron, less than 0.1 micron, greater than 0.01 micron, greater than 0.5 micron, greater than 1 micron, between 1 micron and 2 micron, between 0.5 and 3 micron, between 0.3 micron and 10 micron, etc. Each scattering structure may have a width 274 of less than 5 micron, less than 3 micron, less than 2 micron, less than 1 micron, less than 0.5 micron, less than 0.1 micron, greater than 0.01 micron, greater than 0.5 micron, greater than 1 micron, between 1 micron and 2 micron, between 0.5 micron and 3 micron, between 0.5 micron and 1.5 micron, between 0.3 micron and 10 micron, etc. The pitch 276 may be less than 5 micron, less than 3 micron, less than 2 micron, less than 1 micron, less than 0.5 micron, less than 0.1 micron, greater than 0.01 micron, greater than 0.5 micron, greater than 1 micron, between 1 micron and 2 micron, between 0.5 micron and 3 micron, between 0.5 micron and 1.5 micron, between 0.3 micron and 10 micron, etc. The ratio of the width 274 to the pitch 276 may be referred to as the duty cycle or the etch percentage for the substrate. The duty cycle (etch percentage) indicates how much unetched substrate is present between each pair of scattering structures and how much of the upper surface of the substrate is etched to form the light scattering structures. The ratio may be 100% (e.g., each scattering structure is immediately adjacent to surrounding scattering structures), lower than 100%, lower than 90%, lower than 70%, lower than 60%, greater than 50%, greater than 70%, between (and including) 50% and 100%, etc. The semiconductor substrate may have a thickness of greater than 4 micron, greater than 6 micron, greater than 8 micron, greater than 10 micron, greater than 12 micron, less than 12 micron, between 4 and 10 micron, between 5 and 20 micron, less than 10 micron, less than 6 micron, less than 4 micron, less than 2 micron, greater than 1 micron, etc.

In the example of FIG. 7, the scattering structures 270 have angled sidewalls (e.g., sidewalls that are non-orthogonal and non-parallel to back surface 256). The scattering structures may be pyramidal or may have a triangular cross-section that extends along a longitudinal axis (e.g., a triangular prism). The non-orthogonal angle may be greater than 10 degrees, greater than 30 degrees, greater than 60 degrees, less than 80 degrees, between 20 and 70 degrees, etc. The example of angled sidewalls in FIG. 7 is merely illustrative. The scattering structures may have vertical sidewalls (orthogonal to surface 256) if desired.

The arrangement and dimensions of scattering structures 270 may be selected to optimize the conversion of incident light for the particular SPAD-based semiconductor device. The light scattering structures may have a uniform density (number of light scattering structures per unit area). Alternatively, the light scattering structures may have a non-uniform density. Arranging light scattering structures with a non-uniform density in this manner may help direct light to SPAD 204 in an optimal manner. In general, etching substrate 254 (e.g., to form light scattering structures) may cause an increase in dark current in the SPAD-based semiconductor device. Accordingly, light scattering structures may be omitted where possible to minimize dark current while still optimizing absorption. Omitting light scattering structures may include reducing the density of the light scattering structures to a non-zero magnitude or entirely omitting the light scattering structures in a certain area of the microcell (e.g., to a density of zero).

One or more microlenses may optionally be formed over SPAD 204. In one possible arrangement, a single microlens may cover each respective SPAD 204 in semiconductor device 14. However, the single microlens may need to be thicker than desired to adequately focus light on large SPADs. Thick microlenses of this type may present difficulties during manufacturing.

As shown in FIG. 7, each SPAD 204 may instead be covered by a plurality of microlenses. SPAD 204 in FIG. 7 is covered by a plurality of microlenses 262-1 having a first size and a plurality of microlenses 262-2 having a second size. Microlenses 262-1 may focus light onto the underlying scattering structures 270. In particular, the microlenses may be sized and aligned such that the center of each microlens is aligned in the Z-direction with the trough of an underlying light scattering structure trench.

Microlenses 262-1 have a height 282 (sometimes referred to as thickness) and a width 284. The microlenses also have a pitch 286 (e.g., the center-to-center separation between each microlens). Height 282 may be less than 2 microns, less than 1 micron, less than 500 nanometers, greater than 100 nanometers, between 300 nanometers and 1 micron, etc. Width 284 may be less than 5 micron, less than 3 micron, less than 2 micron, less than 1 micron, less than 0.5 micron, less than 0.1 micron, greater than 0.01 micron, greater than 0.5 micron, greater than 1 micron, between 1 and 2 micron, between 0.5 and 3 micron, between 0.5 micron and 1.5 micron, between 0.3 micron and 10 micron, etc. Pitch 286 may be less than 5 micron, less than 3 micron, less than 2 micron, less than 1 micron, less than 0.5 micron, less than 0.1 micron, greater than 0.01 micron, greater than 0.5 micron, greater than 1 micron, between 1 and 2 micron, between 0.5 and 3 micron, between 0.5 micron and 1.5 micron, between 0.3 micron and 10 micron, etc.

The microlens width 284 may be within 1% of the scattering structure width 274, within 5% of the scattering structure width 274, within 10% of the scattering structure width 274, within 15% of the scattering structure width 274, within 20% of the scattering structure width 274, etc. The microlens pitch 286 may be within 1% of the scattering structure pitch 276, within 5% of the scattering structure pitch 276, within 10% of the scattering structure pitch 276, within 15% of the scattering structure pitch 276, within 20% of the scattering structure pitch 276, etc.

Having each microlens 262-1 aligned with a respective light scattering structure may improve the light scattering efficiency of the light scattering structures 270. However, near the periphery of the microcell, microlenses 262-2 may be larger to ensure that light is focused away from isolation structures 252 and into SPAD 204. Microlenses 262-2 are therefore larger than microlenses 262-1. Microlenses 262-2 have a height 292 (sometimes referred to as thickness) and a width 294. Height 292 may be less than 2 microns, less than 1 micron, less than 500 nanometers, greater than 100 nanometers, between 300 nanometers and 1 micron, etc. In some cases, height 292 of microlenses 262-2 may be greater than height 282 of microlenses 262-1. In other cases, height 292 of microlenses 262-2 may be the same as height 282 of microlenses 262-1.

Width 294 may be less than 10 micron, less than 5 micron, less than 3 micron, less than 2 micron, less than 1 micron, less than 0.5 micron, less than 0.1 micron, greater than 0.01 micron, greater than 0.5 micron, greater than 1 micron, between 1 and 2 micron, between 0.5 and 3 micron, between 0.3 micron and 10 micron, etc. Width 294 of microlenses 262-2 may be greater than width 284 of microlenses 262-1 (e.g., by more than 20%, by more than 50%, by more than 100%, by more than 200%, by more than 300%, etc.). Microlenses 262-2 may be sufficiently large to focus light directed to isolation structures 252 away from the isolation structures and into the microcell. The focal point of microlenses 262-2 may overlap SPAD 204 (as opposed to isolation structures 252).

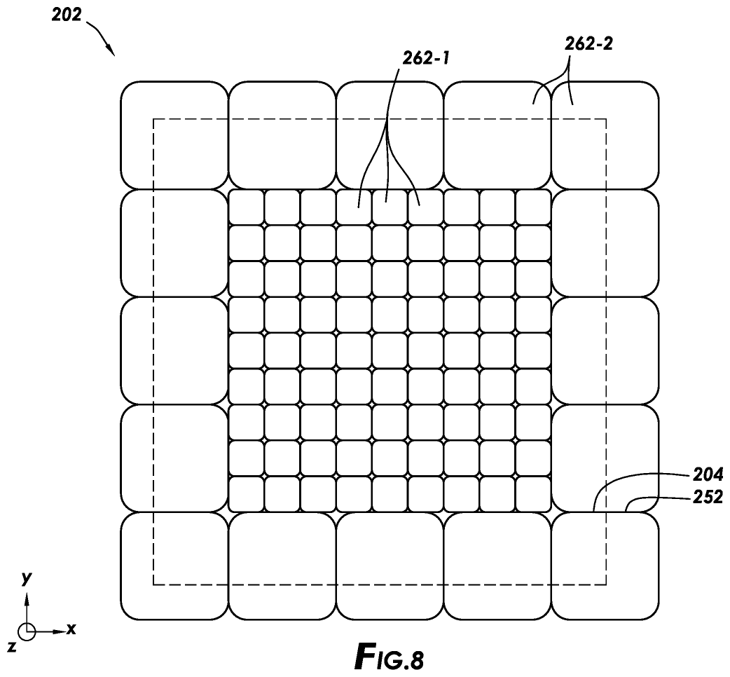

FIG. 8 is a top view of an illustrative microcell (e.g., from FIG. 7) showing the arrangement of microlenses 262-1 and 262-2. The dashed line indicates the border (within the XY-plane) between SPAD 204 and isolation structures 252. An array of microlenses 262-1 is formed over the central portion of the SPAD. The array of microlenses 262-1 may have any desired number of rows and columns (e.g., more than two, more than four, at least five, more than seven, more than ten, more than fifteen, etc.). Microlenses 262-2 are formed around the periphery of the SPAD and laterally surround the central microlenses 262-1. Microlenses 262-2 may partially overlap isolation structures 252 around the periphery of the microcell.

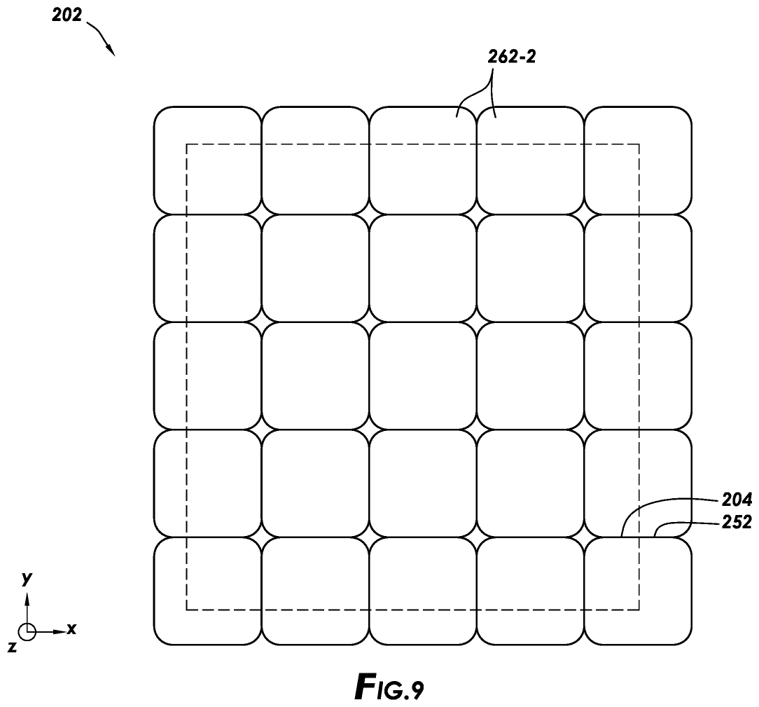

The example in FIGS. 7 and 8 of including microlenses of different sizes over each SPAD is merely illustrative. Another possible option, shown in FIG. 9, is to include an array of microlenses of a uniform size over each SPAD. In this example, all of the microlenses have the dimensions of microlenses 262-2 in FIGS. 7 and 8. This ensures that light is focused away from isolation structures 252 and towards SPAD 204. The light scattering structures may not be as efficient in FIG. 9 (with larger microlenses having a greater width/pitch than the light scattering structures) as in FIGS. 7 and 8 (with the smaller microlenses aligned with the light scattering structures). However, the cost and complexity of manufacturing the microlenses in the arrangement of FIG. 9 may be lower than in the arrangement of FIGS. 7 and 8.

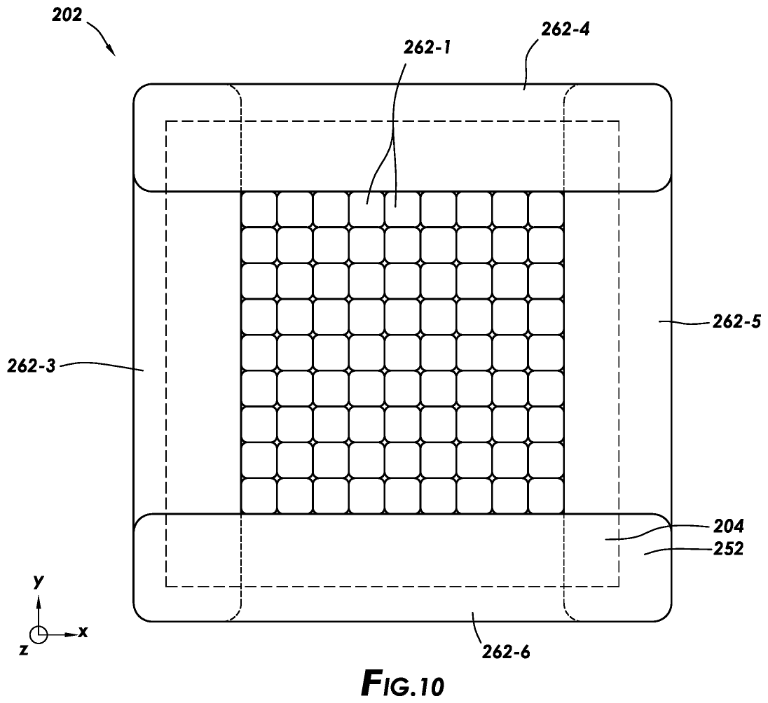

FIG. 10 shows another possible microlens arrangement where cylindrical microlenses are positioned around the periphery of the microcell. As shown in FIG. 10, an array of microlenses 262-1 is formed over the central portion of the SPAD (as previously discussed). Larger microlenses are formed around the periphery of the SPAD (similar to as in FIGS. 7 and 8).

In FIGS. 7-9, the microlenses all may have curved upper surfaces with spherical convex curvature. These types of microlenses may be referred to as spherical microlenses. The spherical microlenses do not necessarily need to have circular footprints and may have footprints that are rectangular with rounded corners, circular, oval, etc.

In contrast with FIGS. 7-9, in FIG. 10, a single cylindrical microlens is formed along each edge of the SPAD (instead of a plurality of discrete spherical microlenses as in FIGS. 7 and 8). Cylindrical microlenses 262-3 and 263-5 extend parallel to the Y-axis in FIG. 10. These microlenses focus light along the X-axis but do not focus light along the Y-axis. Cylindrical microlenses 262-4 and 263-6 extend parallel to the X-axis in FIG. 10. These microlenses focus light along the Y-axis but do not focus light along the X-axis. The cylindrical microlenses in FIG. 10 may avoid any dead (non-focusing) spaces between microlenses and therefore collect more light in the SPADs than when discrete microlenses are used.

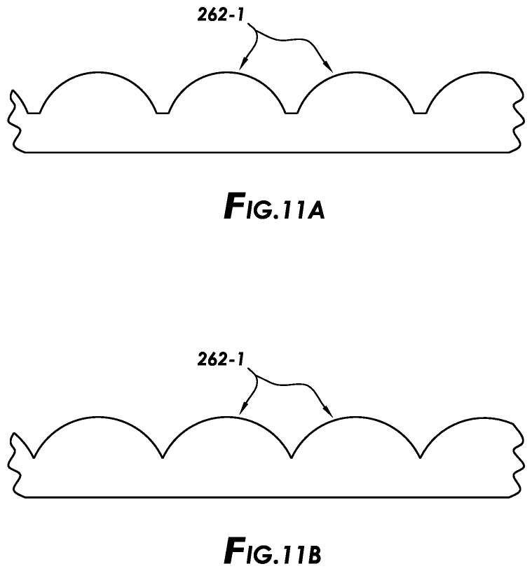

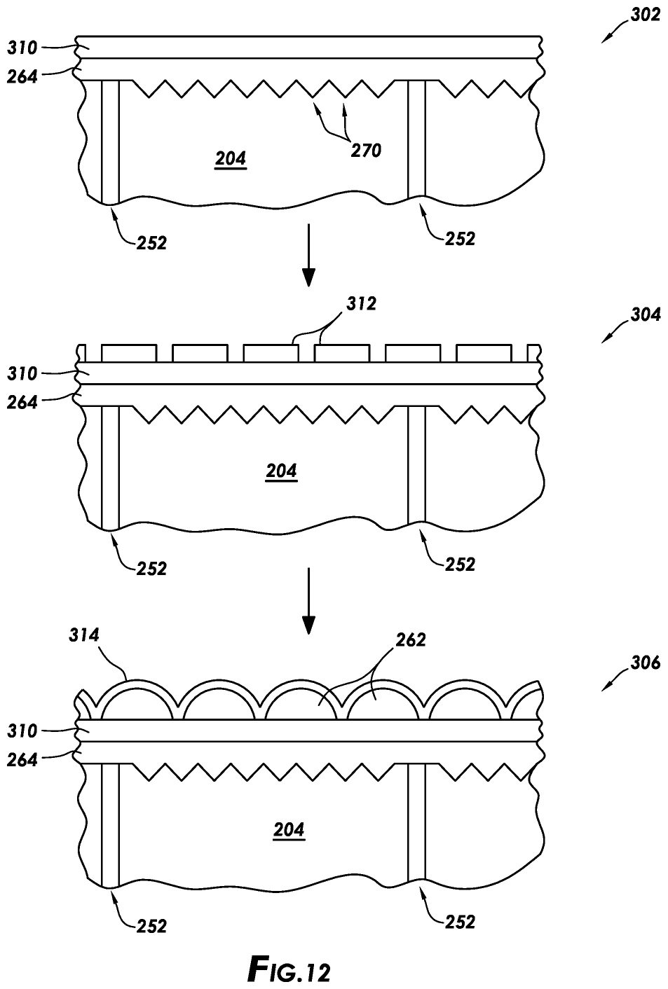

The microlenses herein may be separated by small gaps (as shown in the side view of FIG. 11A) or may be gapless (as shown in the side view of FIG. 11B). The microlenses of FIG. 11A may be formed in a single manufacturing step. To avoid the microlenses merging together during manufacturing (e.g., reflow), a small gap may be included between each adjacent microlens. The gaps between microlenses may be removed (as shown in FIG. 11B) by forming the microlenses in two manufacturing steps. A first half of the microlenses are formed (e.g., reflowed and cured) in a checkerboard pattern. A second half of the microlenses are formed in the gaps of the initial checkerboard pattern, resulting in a complete array of microlenses without gaps. In general, any of the microlens arrays described herein may have gaps or may be gapless, depending upon the specific design constraints for a particular device.

FIG. 12 is a flowchart of illustrative method steps for forming an array of microlenses over each microcell in a SPAD-based semiconductor device. At step 302, an ultraviolet (UV) light absorbing layer 310 (e.g., a blanket layer) may be deposited over the entire substrate. The UV light absorbing layer 310 prevents stray UV light from impacting subsequent photolithography steps. The UV light absorbing layer 310 may also increase the total distance between the upper surface of the microlenses and the SPADs 204. UV light absorbing layer 310 may have a thickness that is greater than 100 nanometers, less than 1000 nanometers, between 100 nanometers and 1000 nanometers, between 200 and 400 nanometers, etc.

At step 304, a patterned layer with microlens portions 312 having planar upper surfaces is formed over layer 310. Each microlens portion 312 is used to form a respective microlens during subsequent steps. The microlens portions 312 may optionally have different widths (e.g., when different microlenses having different sizes cover a single SPAD as in FIGS. 7 and 8). The microlens portions 312 may optionally have different heights (e.g., when different microlenses having different sizes cover a single SPAD as in FIGS. 7 and 8). When the microlens portions 312 have different heights, the microlens portions may be formed in multiple patterning steps. The microlens portions 312 may have centers aligned with underlying light scattering structures 270 (as discussed in connection with FIG. 7). One or more of the microlens portions may be elongated so that the microlens portion forms a cylindrical microlens of the type shown in FIG. 10.

At step 306, reflow is performed (e.g., the microlens portions 312 are heated past their melting point), which defines microlenses 262 with curved upper surfaces. The microlenses may be cured to solidify in this shape (e.g., with curved upper surfaces). An anti-reflective coating (ARC) 314 may also be formed over the microlenses.

In FIG. 12, reflow for all of the microlenses is performed in a single step. The microlenses are therefore separated by gaps (e.g., as shown in FIG. 11A). This example is merely illustrative, and the SPAD-based semiconductor device may instead include gapless microlenses that are formed using multiple reflow steps if desired.

Reflow and curing for microlenses of different sizes may be performed in a single step or in multiple steps (e.g., a first reflow and cure process for the microlenses having the first size and a second reflow and cure process for the microlenses having the second, different size).

SPAD-based semiconductor device 14 may include one or more bond pads in a periphery of the device (e.g., in a region without any active microcells 204). To form the bond pads, the back surface of semiconductor substrate 254 may be etched to form a conductive via to circuitry on a front surface of the semiconductor substrate. During manufacturing, material from layer 310, the microlenses 262, and/or anti-reflective coating 314 may be etched (in addition to substrate 254) to form the bond pad. If each SPAD is covered by a single microlens, the thickness of the materials that need to be etched to form the bond pads may be higher than desired. With the arrangement of FIGS. 7-10 (where each SPAD is covered by an array of microlenses), however, the thickness of the materials that need to be etched to form the bond pads is sufficiently small for easy etching/manufacturing.

The example in FIG. 12 of forming microlenses using reflow is merely illustrative. If desired, the microlenses may be formed using etching or any other desired technique(s).

The foregoing is merely illustrative and various modifications can be made by those skilled in the art. The foregoing embodiments may be implemented individually or in any combination.

What is claimed is:

1. A semiconductor device comprising:
a substrate;
a single-photon avalanche diode formed in the substrate;
first microlenses that overlap the single-photon avalanche diode, wherein each one of the first microlenses has a first size; and
second microlenses that overlap the single-photon avalanche diode, wherein each one of the second microlenses has a second size that is different than the first size.

2. The semiconductor device defined in claim 1, wherein the second size is greater than the first size and wherein the second microlenses overlap a periphery of the single-photon avalanche diode.

3. The semiconductor device defined in claim 2, wherein the second microlenses are cylindrical microlenses.

4. The semiconductor device defined in claim 2, wherein the second microlenses are spherical microlenses.

5. The semiconductor device defined in claim 1, wherein the second size is greater than the first size and wherein the second microlenses extend in a ring around the first microlenses.

6. The semiconductor device defined in claim 1, further comprising:
light scattering structures formed in a surface of the substrate.

7. The semiconductor device defined in claim 6, wherein each one of the first microlenses is aligned with a respective one of the light scattering structures.

8. The semiconductor device defined in claim 6, wherein each one of the first microlenses has a first width, wherein each one of the light scattering structures has a second width, and wherein the first width is within 20% of the second width.

9. The semiconductor device defined in claim 6, wherein the first microlenses are spaced with a first pitch, wherein the light scattering structures are spaced with a second pitch, and wherein the first pitch is within 20% of the second pitch.

10. The semiconductor device defined in claim 1, further comprising:
at least one isolation structure that is formed around the single-photon avalanche diode.

11. The semiconductor device defined in claim 10, wherein each one of the second microlenses at least partially overlaps the at least one isolation structure.

12. An imaging system comprising:
a semiconductor device comprising:
a substrate;
a single-photon avalanche diode formed in the substrate;
at least one isolation structure formed around the single-photon avalanche diode;
first microlenses that overlap a central portion of the single-photon avalanche diode, wherein each one of the first microlenses has a first size; and
second microlenses that at least partially overlap the single-photon avalanche diode and that at least partially overlap the at least one isolation structure, wherein each one of the second microlenses has a second size that is greater than the first size.

13. The imaging system defined in claim 12, wherein the second microlenses are cylindrical microlenses.

14. The imaging system defined in claim 12, wherein the second microlenses are spherical microlenses.

15. The imaging system defined in claim 12, wherein the semiconductor device further comprises:
light scattering structures formed in a surface of the substrate.

16. The imaging system defined in claim 15, wherein each one of the first microlenses is aligned with a respective one of the light scattering structures.

17. The imaging system defined in claim 12, wherein the imaging system is an imaging system for a vehicle.

18. A semiconductor device comprising:
a substrate;
a single-photon avalanche diode formed in the substrate;
at least one isolation structure that is formed in the substrate around the single-photon avalanche diode; and
an array of microlenses that overlaps the single-photon avalanche diode and that at least partially overlaps the at least one isolation structure.

19. The semiconductor device defined in claim 18, wherein the array of microlenses includes at least five rows and at least five columns.

20. The semiconductor device defined in claim 18, further comprising:
light scattering structures comprising trenches in the substrate, wherein the light scattering structures overlap the single-photon avalanche diode and wherein the array of microlenses overlaps the light scattering structures.
